(19) United States
(12) Patent Application Publication
(10) Pub. No.: US 2026/0271663 A1
(43) Pub. Date: Sep. 10, 2026

(54) PASSAGE CHAMBER

(71) Applicant: Samsung Display Co., LTD., Yongin-si (KR)

(72) Inventors: Il Seob YOON, Yongin-si (KR); Min Kook AHN, Yongin-si (KR); Suk Ha RYU, Yongin-si (KR); Byung Gyu CHAE, Yongin-si (KR)

(21) Appl. No.: 19/425,616

(22) Filed: Dec. 18, 2025

(30) Foreign Application Priority Data
Mar. 5, 2025 (KR) 10-2025-0028457
Apr. 16, 2025 (KR) 10-2025-0049621

(51) Int. Cl. H10P 72/10; H10P 72/00

(52) U.S. Cl. CPC H10P 72/1926; H10P 72/0434; H10P 72/0464; H10P 72/1911; H10P 72/1904; H10P 72/1908

(57) ABSTRACT

A passage chamber includes a chamber body in which a substrate is to be accommodated, a heater arranged inside the chamber body, and a vacuum pump arranged at the chamber body, and the vacuum pump includes a pump body connected to an inside of the chamber body, a mesh layer arranged between an inside of the chamber body and the pump body, and a protective cap covering the mesh layer inside the chamber body.

### CROSS-REFERENCE TO RELATED APPLICATIONS

The present application claims priority to and the benefit of Korean Patent Application No. 10-2025-0028457, filed on Mar. 5, 2025, and Korean Patent Application No. 10-2025-0049621, filed on Apr. 16, 2025, in the Korean Intellectual Property Office, the entire disclosures of both of which are incorporated herein by reference.

### BACKGROUND

### 1. Field

Aspects of embodiments of the present disclosure relate to a passage chamber.

### 2. Description of the Related Art

During processes of fabricating display devices, it is important to maintain a constant temperature in a process of forming organic light-emitting diodes (OLEDs), thin films of liquid-crystal displays (LCDs) and micro LEDs, etc. In particular, temperature changes during the process of forming thin films may directly affect deposition uniformity and process efficiency.

In order to maintain temperature during a fabrication process, a passage chamber may be included in the fabrication equipment for display devices. A passage chamber maintains the process environment while a display panel moves. The passage chamber controls the internal temperature within a particular range to reduce temperature changes on the surface of the display panel. The passage chamber is usually connected to the process chamber.

### SUMMARY

According to an aspect of embodiments of the present disclosure, a passage chamber that can maintain a constant temperature of a substrate accommodated inside a chamber body is provided.

However, aspects of the present disclosure are not restricted to those set forth herein. The above and other aspects of the present disclosure will become more apparent to one of ordinary skill in the art to which the present disclosure pertains by referencing the detailed description of the present disclosure provided below.

According to one or more embodiments of the present disclosure, a passage chamber includes a chamber body in which a substrate is to be accommodated, a heater arranged inside the chamber body, and a vacuum pump arranged at the chamber body, wherein the vacuum pump includes a pump body connected to an inside of the chamber body, a mesh layer arranged between an inside of the chamber body and the pump body, and a protective cap covering the mesh layer inside the chamber body.

In one or more embodiments, the vacuum pump further includes an absorbent layer arranged on the protective cap.

In one or more embodiments, the absorbent layer is arranged to entirely cover an upper surface of the protective cap.

In one or more embodiments, the heater is arranged above the substrate, and the vacuum pump is arranged under the substrate.

In one or more embodiments, the pump body is arranged on a bottom of the chamber body, and the protective cap is extended from an inner surface of the chamber body to an inner side of the chamber body.

In one or more embodiments, the vacuum pump is arranged between a center and an edge of the chamber body.

In one or more embodiments, a communication area is located to connect the inside of the chamber body with the pump body in the protective cap.

In one or more embodiments, the communication area is formed by removing a part of a side surface of the protective cap.

In one or more embodiments, an upper surface of the protective cap is formed as a curved surface.

In one or more embodiments, the upper surface of the protective cap is convex upward.

In one or more embodiments, a central area of the upper surface of the protective cap is higher than an edge area thereof.

In one or more embodiments, the passage chamber further includes a window arranged at the chamber body so as to be spaced apart from the vacuum pump.

In one or more embodiments, the window includes a plurality of windows, and windows of the plurality of windows are spaced apart from each other at an edge of the chamber body.

In one or more embodiments, the window includes a plurality of windows, and windows of the plurality of windows are arranged at corners of the chamber body, respectively.

In one or more embodiments, the window is at a bottom of the chamber body.

In one or more embodiments, the passage chamber further includes a reflective layer on an upper surface of the window.

In one or more embodiments, the reflective layer is arranged to entirely cover the upper surface of the window.

In one or more embodiments, an upper surface of the window is formed as a curved surface.

In one or more embodiments, the upper surface of the window is concave upward.

In one or more embodiments, a central area of the upper surface of the window is lower than an edge area thereof.

According to one or more embodiments of the present disclosure, an absorbent layer is arranged on a protective cap of a vacuum pump, and a reflective layer is arranged on a window in a passage chamber, such that a temperature of a substrate accommodated inside the chamber body can be maintained constant or substantially constant.

However, aspects and effects according to the embodiments of the present disclosure are not limited to those mentioned above and other aspects and effects are included in, or will be understood from, the following description of the present disclosure.

### BRIEF DESCRIPTION OF THE DRAWINGS

The above and other aspects and features of the present disclosure will become more apparent by describing in further detail some example embodiments thereof with reference to the attached drawings.

FIG. 1 is a plan view of a passage chamber according to an embodiment of the present disclosure.

FIG. 2 is a cross-sectional view taken along the line A-A′ of FIG. 1.

FIG. 3 is a cross-sectional view taken along the line B-B′ of FIG. 1.

FIG. 4 is an enlarged view of a region “C” of FIG. 2.

FIG. 5 is an enlarged view of a region “D” of FIG. 3.

FIG. 6 is a view showing another example of the passage chamber shown in FIG. 2.

FIG. 7 is an enlarged view of a region “E” of FIG. 6.

FIG. 8 is a view showing another example of the passage chamber shown in FIG. 3.

FIG. 9 is an enlarged view of a region “F” of FIG. 8.

### DETAILED DESCRIPTION

Aspects, advantages, and features of the present disclosure and methods to achieve them will become apparent from the descriptions of some example embodiments herein with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined by the claims.

As used herein, a phrase “an element A on an element B” refers to that the element A may be disposed directly on the element B and/or that the element A may be disposed indirectly on the element B via another element C. Like reference numerals denote like elements throughout the descriptions. The figures, dimensions, ratios, angles, numbers of elements given in the drawings are illustrative and are not limiting.

Although terms such as “first,” “second,” etc. may be used to distinguish between the elements such terms describe, these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be appreciated by those skilled in the art, technically various interactions and operations are possible. Various example embodiments can be practiced individually or in combination.

Herein, some example embodiments of the present disclosure will be described in further detail with reference to the accompanying drawings.

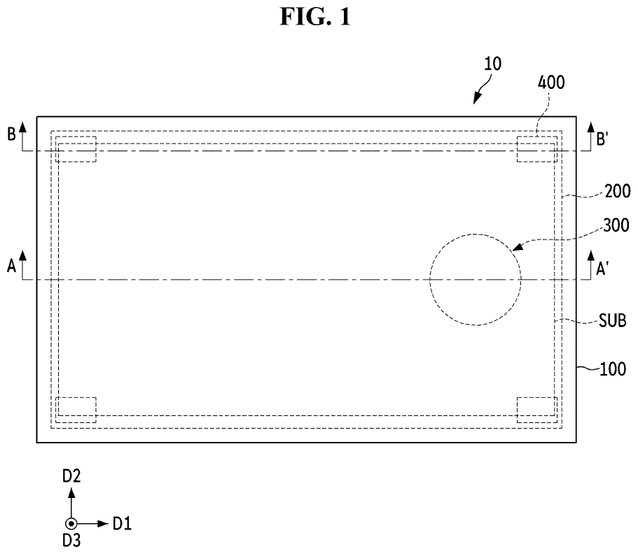

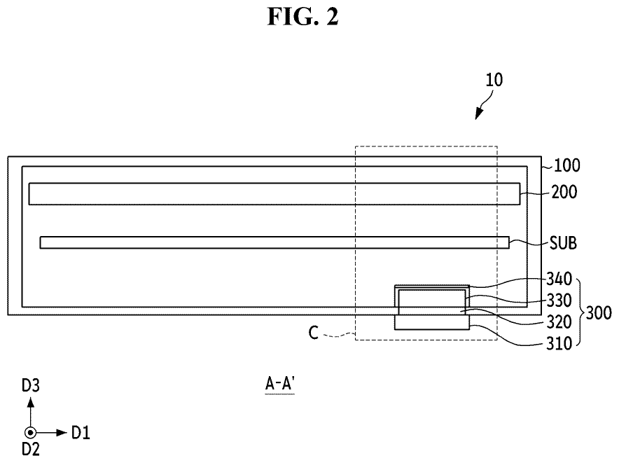

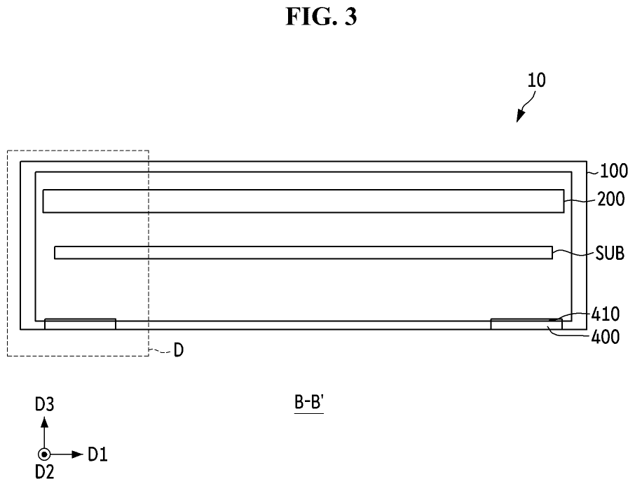

FIG. 1 is a plan view of a passage chamber according to an embodiment of the present disclosure. FIG. 2 is a cross-sectional view taken along the line A-A′ of FIG. 1. FIG. 3 is a cross-sectional view taken along the line B-B′ of FIG. 1.

Referring to FIGS. 1 to 3, a passage chamber 10 according to an embodiment of the present disclosure may include a chamber body 100, a heater 200, a vacuum pump 300, and a window 400.

The chamber body 100 may accommodate a substrate SUB. An accommodation space for accommodating the substrate SUB may be formed inside the chamber body 100. The chamber body 100 may protect the substrate SUB so as to minimize or reduce influence from an external environment while the substrate SUB moves to a process chamber (not shown). An opening (not shown) for loading and unloading the substrate SUB may be formed at a side of the chamber body 100. In an embodiment, the opening may be closed or opened by a door (not shown). The opening may be opened while the substrate SUB is loaded into the chamber body 100 or unloaded from the chamber body 100. The inside of the chamber body 100 may be maintained at a constant (constant or substantially constant) temperature while the substrate SUB is accommodated therein.

The chamber body 100 may include a bottom, a ceiling opposite the bottom, and side walls surrounding the bottom and the ceiling to form the accommodation space. The bottom of the chamber body 100 may be parallel to a surface defined by a first direction D1 and a second direction D2. The side walls of the chamber body 100 may be extended in a third direction D3 that is normal to the bottom to connect the bottom with the ceiling of the chamber body 100.

In an embodiment, the chamber body 100 may be fabricated of a metal, such as stainless steel or an aluminum alloy, and may be fabricated in consideration of thermal conductivity and vacuum resistance.

The heater 200 may be located in an internal accommodation space of the chamber body 100. The heater 200 may supply heat to the internal accommodation space of the chamber body 100. The heater 200 may be placed above the substrate SUB in the internal accommodation space of the chamber body 100. For example, if the substrate SUB is placed in the central area of the internal accommodation space of the chamber body 100, the heater 200 may be located above the substrate SUB so as to be adjacent to the ceiling of the chamber body 100. The heater 200 may supply heat to the substrate SUB by applying heat to the internal accommodation space of the chamber body 100.

The heater 200 may be provided as an electric resistance heater, an infrared heater, a flexible heater, etc. In an embodiment, the heater 200 may be provided as a multi-zone heater such that heat can be evenly (evenly or substantially evenly) provided to the substrate SUB. A separate temperature sensor (not shown) may be placed inside the chamber body 100. The heater 200, in cooperation with the temperature sensor, may supply heat to the internal accommodation space of the chamber body 100 such that the temperature of the internal accommodation space of the chamber body 100 is maintained.

The vacuum pump 300 may be placed at the chamber body 100 to maintain the internal accommodation space of the chamber body 100 in a vacuum state. The vacuum pump 300 may be placed between the center and the edge of the chamber body 100 on the bottom of the chamber body 100. The vacuum pump 300 may be placed under the substrate SUB. In an embodiment, the vacuum pump 300 may include a pump body 310, a mesh layer 320, a protective cap 330, and an absorbent layer 340.

The pump body 310 may be connected to the inside of the chamber body 100. The pump body 310 may be placed on the bottom of the chamber body 100. For example, the pump body 310 may be placed under the bottom of the chamber body 100 outside the chamber body 100. The pump body 310 may penetrate a part of the bottom of the chamber body 100 and be connected to the internal accommodation space of the chamber body 100.

The pump body 310 may discharge gas inside the chamber body 100 to maintain the internal accommodation space of the chamber body 100 in a vacuum state. In an embodiment, the pump body 310 may be provided as a turbo molecular pump (TMP), a cryo-pump, a dry scroll pump, etc.

The mesh layer 320 may be placed between the internal accommodation space of the chamber body 100 and the pump body 310. For example, the mesh layer 320 may be placed on the bottom of the chamber body 100 penetrated by the pump body 310.

The mesh layer 320 may regulate the flow of gas discharged from the internal accommodation space of the chamber body 100 to induce uniform discharge of the gas, and may prevent or substantially prevent foreign substances from entering the pump body 310. In an embodiment, the mesh layer 320 may have a porous structure made of stainless steel or ceramic material.

The protective cap 330 may be placed in the internal accommodation space of the chamber body 100 to cover the mesh layer 320. For example, the protective cap 330 may be extended from the internal bottom of the chamber body 100 in the third direction D3 to cover the mesh layer 320. The upper surface of the protective cap 330 may be located higher than the bottom of the chamber body 100. A space for gas to flow may be formed inside the protective cap 330.

A communication area (not shown) for communicating the internal accommodation space of the chamber body 100 with the pump body 310 may be formed at the protective cap 330. The communication area may be formed by removing a part of the side surface of the protective cap 330.

The absorbent layer 340 may be placed on the protective cap 330. For example, the absorbent layer 340 may cover the upper surface of the protective cap 330 on the upper surface of the protective cap 330. The absorbent layer 340 may have an area corresponding to the upper surface of the protective cap 330 and may cover the entire upper surface of the protective cap 330.

In an embodiment, the absorbent layer 340 may be provided as a glass having a high heat absorption rate, or may be provided as a sand-coated metal layer. The absorbent layer 340 may absorb a part of the heat passing through the substrate SUB.

The window 400 may be arranged at the chamber body 100 so as to be spaced apart from the vacuum pump 300. In an embodiment, a plurality of windows 400 may be provided. In an embodiment, the windows 400 may be arranged at the edge of the bottom of the chamber body 100 so as to be spaced apart from each other. For example, the windows 400 may be arranged at the respective corners of the bottom of the chamber body 100. The windows 400 may be arranged so as to penetrate a part of the bottom of the chamber body 100.

A state of the internal accommodation space of the chamber body 100 can be checked from the outside of the chamber body 100 through the plurality of windows 400. In an embodiment, the plurality of windows 400 may include heat-resistant glass (quartz glass) or sapphire glass to have high durability. The windows 400 may be formed to maintain durability even in a vacuum and high-temperature environment.

In an embodiment, reflective layers 410 may be arranged on upper surfaces of the windows 400, respectively. For example, the reflective layers 410 may cover the upper surfaces of the windows 400 on the upper surfaces of the windows 400, respectively. In an embodiment, each of the reflective layers 410 may have an area corresponding to the upper surfaces of the respective windows 400 and cover the entire upper surface of the respective windows 400.

In an embodiment, the reflective layers 410 may be provided as low-emissivity coated glass. The reflective layers 410 may reflect a part of the heat passing through the substrate SUB.

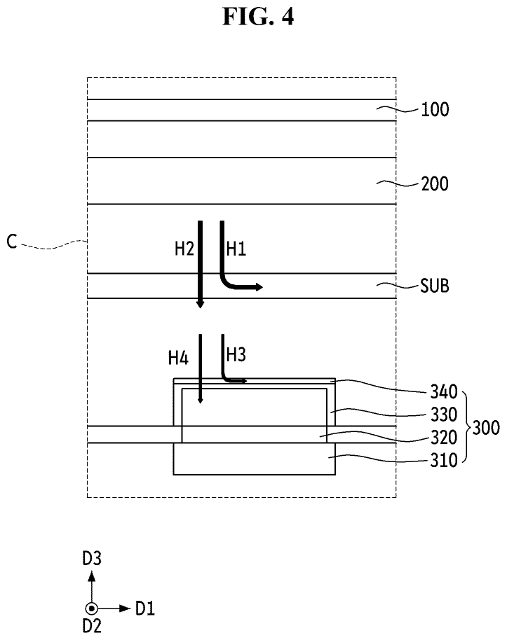

FIG. 4 is an enlarged view of a region “C” of FIG. 2.

Referring to FIG. 4, a part of the heat supplied from the heater 200 may be absorbed by the substrate SUB, and another part of the heat may pass through the substrate SUB. For example, among the heat supplied from the heater 200, first heat H1 may be absorbed by the substrate SUB, while second heat H2 may pass through the substrate SUB. In an embodiment, the first heat H1 absorbed by the substrate SUB may be approximately 80% of the heat supplied from the heater 200, and the second heat H2 passing through the substrate SUB may be approximately 20% of the heat supplied from the heater 200. In some embodiments, approximately 80% of the heat supplied from the heater 200 is absorbed by the substrate SUB, and the remaining 20% may pass through the substrate SUB.

A part of the second heat H2 that has passed through the substrate SUB may be absorbed by the absorbent layer 340, and another part of the heat may pass through the absorbent layer 340 and the protective cap 330. For example, among the second heat H2 that has passed through the substrate SUB, third heat H3 may be absorbed by the absorbent layer 340, and fourth heat H4 may pass through the absorbent layer 340 and the protective cap 330. In an embodiment, the third heat H3 absorbed by the absorbent layer 340 may be approximately 16% of the heat supplied from the heater 200 (or 80% of the second heat H2 passing through the substrate SUB), and the fourth heat H4 passing through the absorbent layer 340 and the protective cap 330 may be approximately 4% of the heat supplied from the heater 200 (or 20% of the second heat H2 passing through the substrate SUB).

As described above, a part of the heat passing through the substrate SUB is absorbed by the absorbent layer 340, and another part of the heat passes through the absorbent layer 340 and the protective cap 330, such that the heat passing through the substrate SUB is not entirely reflected. Accordingly, only the heat directly supplied from the heater 200 is supplied to the substrate SUB, and the other heat is not supplied to the substrate SUB, such that the temperature of the substrate SUB located above the vacuum pump 300 can be prevented or substantially prevented from increasing.

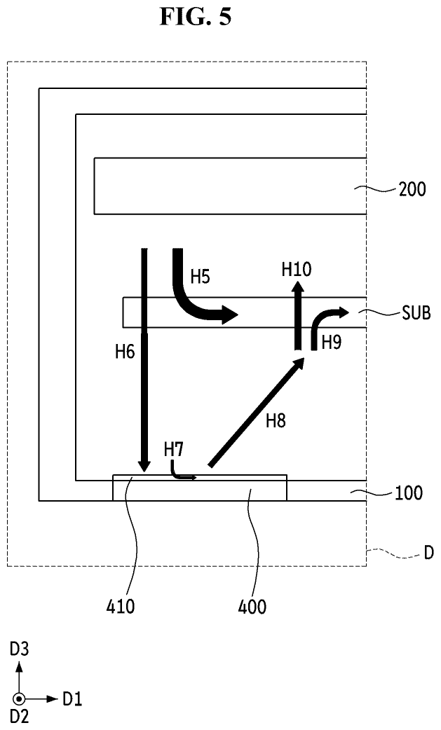

FIG. 5 is an enlarged view of a region “D” of FIG. 3.

Referring to FIG. 5, a part of the heat supplied from the heater 200 may be absorbed by the substrate SUB, and another part of the heat may pass through the substrate SUB. For example, among the heat supplied from the heater 200, fifth heat H5 may be absorbed by the substrate SUB, while sixth heat H6 may pass through the substrate SUB. In an embodiment, the fifth heat H5 absorbed by the substrate SUB may be approximately 80% of the heat supplied from the heater 200, and the sixth heat H6 passing through the substrate SUB may be approximately 20% of the heat supplied from the heater 200. In some embodiments, approximately 80% of the heat supplied from the heater 200 is absorbed by the substrate SUB, and the remaining 20% may pass through the substrate SUB.

A part of the sixth heat H6 that has passed through the substrate SUB may be absorbed by the reflective layer 410, and another part of the heat may be reflected by the reflective layer 410. For example, among the sixth heat H6 that has passed through the substrate SUB, seventh heat H7 may be absorbed by the reflective layer 410, and eighth heat H8 may be reflected by the reflective layer 410. In an embodiment, the seventh heat H7 absorbed by the reflective layer 410 may be approximately 1% of the heat supplied from the heater 200 (or 5% of the sixth heat H6 passing through the substrate SUB), and the eighth heat H8 reflected by the reflective layer 410 may be approximately 19% of the heat supplied from the heater 200 (or 95% of the sixth heat H6 passing through the substrate SUB).

A part of the eighth heat H8 that is reflected by the reflective layer 410 may be absorbed by the substrate SUB, and another part of the heat may pass through the substrate SUB. For example, among the eighth heat H8 reflected by the reflective layer 410, ninth heat H9 may be absorbed by the substrate SUB, while tenth heat H10 may pass through the substrate SUB. In an embodiment, the ninth heat H9 absorbed by the substrate SUB may be approximately 15.2% of the heat supplied from the heater 200 (or 80% of the eighth heat H8 reflected by the reflective layer 410), and the tenth heat H10 passing through the substrate SUB may be approximately 3.8% of the heat supplied from the heater 200 (or 20% of the eighth heat H8 reflected by the reflective layer 410).

As described above, only a small amount of the heat passing through the substrate SUB may be absorbed by the reflective layer 410, and most of the heat may be reflected to the substrate SUB through the reflective layer 410. The heat reflected toward the substrate SUB may be reabsorbed by the substrate SUB and may increase the temperature of the substrate SUB located above the window 400. In this manner, it is possible to prevent or substantially prevent the temperature of the substrate SUB located above the window 400 from decreasing.

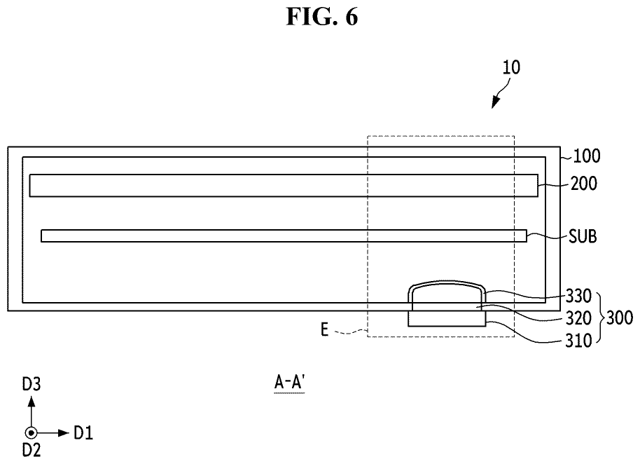

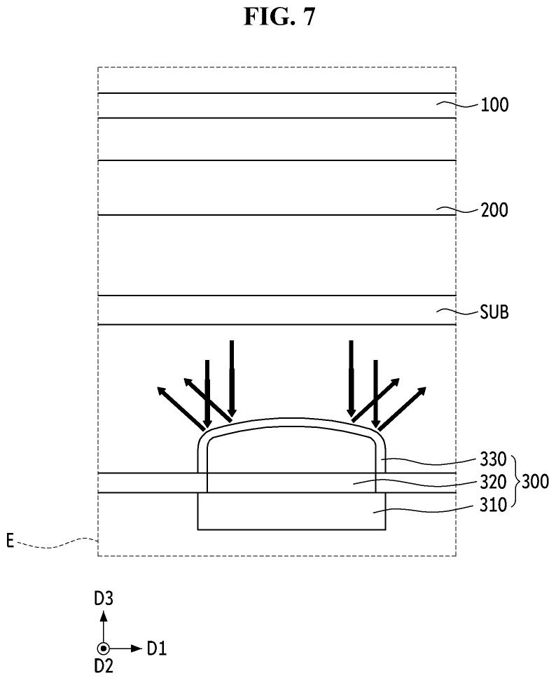

FIG. 6 is a view showing another example of the passage chamber shown in FIG. 2. FIG. 7 is an enlarged view of a region “E” of FIG. 6.

Referring to FIGS. 6 and 7, in an embodiment, the absorbent layer 340 is not arranged on the protective cap 330, and the upper surface of the protective cap 330 may be formed as a curved surface. For example, the upper surface of the protective cap 330 may be convex upward in the third direction D3. A central area of the upper surface of the protective cap 330 may be located higher than an edge thereof in the third direction D3.

In an embodiment, the upper surface of the protective cap 330 is convex in the third direction D3, and the heat passing through the substrate SUB may be reflected off the upper surface of the protective cap 330 and may diffuse. For example, the heat passing through the substrate SUB may be reflected to left and right sides in the first direction D1 according to the curvature of the upper surface of the protective cap 330. The heat reflected off the upper surface of the protective cap 330 is reflected to the left and right sides in the first direction D1 and diffuses, and, thus, the heat is not transferred to the substrate SUB located above the vacuum pump 300. In this manner, it is possible to prevent or substantially prevent the temperature of the substrate SUB located above the vacuum pump 300 from increasing.

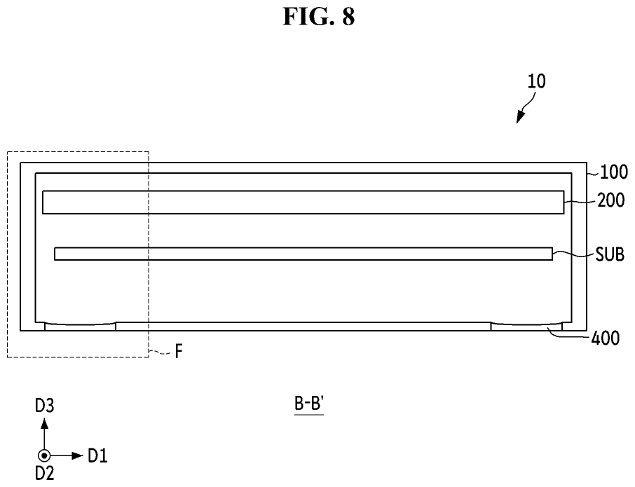

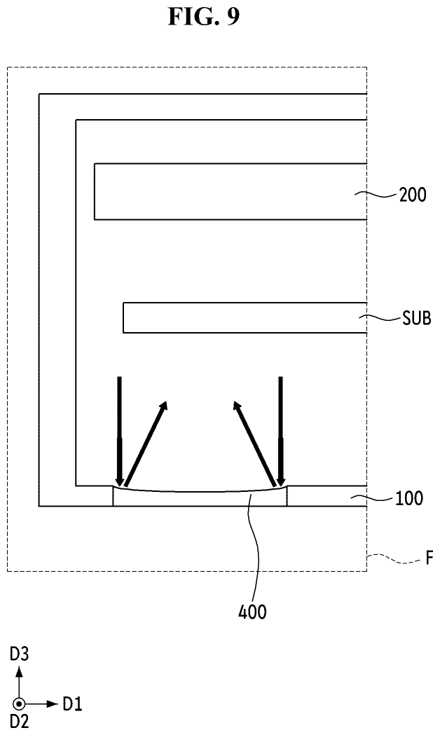

FIG. 8 is a view showing another example of the passage chamber shown in FIG. 3. FIG. 9 is an enlarged view of a region “F” of FIG. 8.

Referring to FIGS. 8 and 9, in an embodiment, the reflective layer 410 is not arranged on the upper surface of the window 400, and the upper surface of the window 400 may be formed as a curved surface. For example, the upper surface of the window 400 may be concave in the third direction D3. A central area of the upper surface of the window 400 may be located lower than an edge thereof in the third direction D3.

In an embodiment, the upper surface of the window 400 is concave in the third direction D3, and the heat passing through the substrate SUB may be reflected off the upper surface of the window 400 and may be transferred to the substrate SUB. For example, the heat passing through the substrate SUB may be reflected in the third direction D3 according to the curvature of the upper surface of the window 400. The heat reflected off the upper surface of the window 400 may be reflected in the third direction D3 and transferred to the substrate SUB located above the window 400. The heat transferred to the substrate SUB may be reabsorbed by the substrate SUB and may increase the temperature of the substrate SUB located above the window 400. In this manner, it is possible to prevent or substantially prevent the temperature of the substrate SUB located above the window 400 from decreasing.

Although some example embodiments have been described herein, it is to be understood that aspects and features of embodiments of the present disclosure are not restricted to those set forth herein. The above and other aspects of the present disclosure will become more apparent to one of ordinary skill in the art to which the present disclosure pertains by referencing the claims, with equivalents thereof to be included therein.

What is claimed is:

1. A passage chamber comprising:
a chamber body in which a substrate is to be accommodated;
a heater arranged inside the chamber body; and
a vacuum pump arranged at the chamber body,
wherein the vacuum pump comprises:
a pump body connected to an inside of the chamber body;
a mesh layer arranged between the inside of the chamber body and the pump body; and
a protective cap covering the mesh layer inside the chamber body.

2. The passage chamber of claim 1, wherein the vacuum pump further comprises an absorbent layer arranged on the protective cap.

3. The passage chamber of claim 2, wherein the absorbent layer is arranged to entirely cover an upper surface of the protective cap.

4. The passage chamber of claim 1, wherein the heater is arranged above the substrate, and the vacuum pump is arranged under the substrate.

5. The passage chamber of claim 4, wherein the pump body is arranged at a bottom of the chamber body, and
wherein the protective cap is extended from an inner surface of the chamber body to an inner side of the chamber body.

6. The passage chamber of claim 1, wherein the vacuum pump is arranged between a center and an edge of the chamber body.

7. The passage chamber of claim 1, wherein a communication area is defined to connect the inside of the chamber body with the pump body in the protective cap.

8. The passage chamber of claim 7, wherein the communication area is formed by removing a part of a side surface of the protective cap.

9. The passage chamber of claim 1, wherein an upper surface of the protective cap is formed as a curved surface.

10. The passage chamber of claim 9, wherein the upper surface of the protective cap is convex upward.

11. The passage chamber of claim 10, wherein a central area of the upper surface of the protective cap is higher than an edge area thereof.

12. The passage chamber of claim 1, further comprising:
a window arranged at the chamber body so as to be spaced apart from the vacuum pump.

13. The passage chamber of claim 12, wherein the window comprises a plurality of windows, and
wherein windows of the plurality of windows are spaced apart from each other at an edge of the chamber body.

14. The passage chamber of claim 12, wherein the window comprises a plurality of windows, and
wherein windows of the plurality of windows are arranged at corners of the chamber body, respectively.

15. The passage chamber of claim 12, wherein the window is at a bottom of the chamber body.

16. The passage chamber of claim 15, further comprising a reflective layer on an upper surface of the window.

17. The passage chamber of claim 16, wherein the reflective layer is arranged to entirely cover the upper surface of the window.

18. The passage chamber of claim 12, wherein an upper surface of the window is formed as a curved surface.

19. The passage chamber of claim 18, wherein the upper surface of the window is concave upward.

20. The passage chamber of claim 19, wherein a central area of the upper surface of the window is lower than an edge area.
